(19) United States
(12) Patent Application Publication
(10) Pub. No.: US 2023/0096510 A1
(43) Pub. Date: Mar. 30, 2023

(54) LIGHT-EMITTING DEVICE AND DISPLAY SUBSTRATE

(71) Applicant: BOE TECHNOLOGY GROUP CO., LTD., Beijing (CN)

(72) Inventors: Haiyan SUN, Beijing (CN); Xiaojin ZHANG, Beijing (CN)

(21) Appl. No.: 17/789,683

(22) PCT Filed: Sep. 1, 2021
(86) PCT No.: PCT/CN2021/115907

§ 371 Date: Jun. 28, 2022

(30) Foreign Application Priority Data
Oct. 16, 2020 (CN) 202011112314.2

(51) Int. Cl. H01L 51/50; H01L 51/00

(52) U.S. Cl. CPC H01L 51/5016; H01L 51/5036; H01L 51/0072; H01L 51/0054; H01L 51/0067; H01L 51/0059; H01L 51/0071

(57) ABSTRACT

The embodiments of the present disclosure provide a light-emitting device and a display substrate, which belong to the technical field of organic light-emitting diodes. The light-emitting device of the present disclosure comprises: a first light-emitting layer comprising a first host material and a first guest material; and a second light-emitting layer comprising a second host material and a second guest material; S1(h1)>S1(g1), T1(h1)>T1(g1), S1(g1)−T1(g1)≤0.1 eV; S1(h2)>S1(g2), T1(h2)>T1(g2), S1(g2)−T1(g2)≤0.1 eV; S1(h1)≥S1(h2)>S1(g1)>S1(g2), T1(h1)≥T1(h2)>T1(g1)>T1(g2); the second guest material is a TADF material; at least 40% of the area in a region covered under the emission spectrum of the first light-emitting layer overlaps with the region covered under the absorption spectrum of the second light-emitting layer.

### TECHNICAL FIELD

The embodiments of the present disclosure belong to the technical field of organic light-emitting diodes, and particularly relates to a light-emitting device and a display substrate.

### BACKGROUND

Due to the advantages such as active light emission, fast response, high energy utilization rate, long service life, and easy to realize flexibility, the organic light-emitting diode (OLED) based light-emitting devices are widely used in the field of display and the like.

The light-emitting materials of the organic light-emitting diode mainly include phosphorescent materials and fluorescent materials. The application of the fluorescent materials is greatly limited, because the light-emitting efficiency of the conventional fluorescent materials is lower than that of the phosphorescent materials based on the limitation of light-emitting principle. Fortunately, thermally activated delayed fluorescence (TADF) materials allow the conversion of non-radiative triplet excited states to radiative singlet states by reverse intersystem crossing (RISC), which theoretically can achieve a 100% internal quantum efficiency (IQE); furthermore, the TADF materials usually neither contain heavy metals, nor cause pollution, and thus have wide application prospect.

However, there are still some problems in the practical application of TADF materials in the organic light-emitting diode, such as difficulty in developing host materials with good dual injection property, poor matching between the host materials and the exciton blocking layer, reduction in light-emitting efficiency due to easy generation of carrier imbalance, and performance degradation due to easy generation of interface exciton accumulation.

### SUMMARY

The embodiments of the present disclosure at least partially addressed the problems of the existing organic light-emitting diode adopting the TADF material, such as difficulty in developing host materials, low efficiency and poor performance, and provide a light-emitting device and a display substrate which have the advantages of high efficiency, narrow light-emitting spectrum and easily available materials.

In a first aspect, embodiments of the present disclosure provide a light-emitting device, comprising a cathode, an anode, and both a first light-emitting layer and a second light-emitting layer provided between the cathode and the anode, wherein the first light-emitting layer is located on a side of the second light-emitting layer close to the anode; wherein,

the first light-emitting layer comprises a first host material and a first guest material, and the first host material has a hole mobility higher than an electron mobility;

the second light-emitting layer comprises a second host material and a second guest material, and the second host material has a hole mobility higher than an electron mobility;

S1(h1)>S1(g1), T1(h1)>T1(g1), S1(g1)−T1(g1)≤0.1 eV;

S1(h2)>S1(g2), T1(h2)>T1(g2), S1(g2)−T1(g2)≤0.1 eV;

S1(h1)≥S1(h2)>S1(g1)>S1(g2), T1(h1)≥T1(h2)>T1(g1)>T1(g2);

wherein T1 represents a triplet excitation energy, S1 represents a singlet excitation energy, h1 represents the first host material, h2 represents the second host material, g1 represents the first guest material, and g2 represents the second guest material;

the second guest material is a thermally activated delayed fluorescence material; and

at least 40% of an area in a region covered under a emission spectrum of the first light-emitting layer overlaps with the region covered under a absorption spectrum of the second light-emitting layer.

Optionally, the second guest material has an emission spectrum with a full width at half maximum of 35 nm or less.

Optionally, an energy of a light emitted by the first guest material accounts for less than 20% of total energy of the light emitted by the light-emitting device.

Optionally, in the first light-emitting layer, the first host material has a mass percentage content of between 60% and 95%, and the first guest material has a mass percentage content of between 5% and 40%.

Optionally, in the second light-emitting layer, the second host material has a mass percentage content of between 70% and 99%, and the second guest material has a mass percentage content of between 1% and 30%.

Optionally, at least one of the first host material, the first guest material and the second host material is a thermally activated delayed fluorescence material.

Optionally, the first host material and the second host material are the same material.

Optionally, the first light-emitting layer has a thickness of between 5 nm and 15 nm.

Optionally, the second light-emitting layer has a thickness of between 1 nm and 20 nm.

Optionally, the light-emitting device further comprises at least one of the following structures:

an hole injection layer, a hole transport layer, a hole blocking layer, an electron injection layer, an electron transport layer, an electron blocking layer, a capping layer and a encapsulating layer.

Optionally, the first host material and the second host material are each independently selected from materials having the following general formula 1:

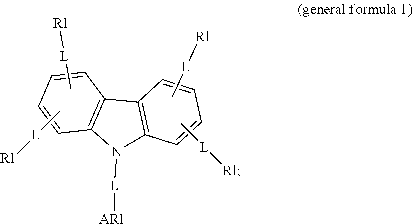

wherein each L is independently selected from any one of a single bond, a substituted C6-C30 arylene group and an unsubstituted C6-C30 arylene group; the single bond refers to that R1 corresponding to L is directly connected with benzene ring through the single bond, or AR1 corresponding to L is directly connected with N through the single bond;

AR1 is selected from any one of a substituted C6-C30 aryl group, an unsubstituted C6-C30 aryl group, a substituted C2-C30 heterocyclic group, an unsubstituted C2-C30 heterocyclic group, a substituted C6-C30 arylamine group, an unsubstituted C6-C30 arylamine group, a substituted C8-C30 group containing aryl and heterocyclic groups, and an unsubstituted C8-C30 group containing aryl and heterocyclic groups;

each R1 is independently selected from any one of hydrogen, a substituted C1-C20 alkyl, an unsubstituted C1-C20 alkyl, a substituted C6-C30 aryl, an unsubstituted C6-C30 aryl, a substituted C2-C30 heterocyclic group, an unsubstituted C2-C30 heterocyclic group, a substituted C8-C30 group containing aryl and heterocyclic groups, an unsubstituted C8-C30 group containing aryl and heterocyclic groups, a substituted nitrile group, an unsubstituted nitrile group, a substituted isonitrile group, an unsubstituted isonitrile group, hydroxyl group and thiol group; R1 connected with different L are not connected with each other, or are connected with each other to form a ring structure;

at least one of AR1 and all R1s is selected from any one of carbazolyl R(a), a substituted carbazolyl R(a), terphenylene R(b), and a substituted terphenylene R(b):

R(a) has a formula of:

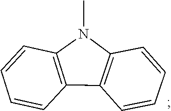

and

R(b) has a formula of:

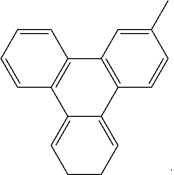 [SMILES: Cc1ccc2c3c(c4ccccc4c2c1)=CCCC=3]

Optionally, the first guest material has the following general formula 2:

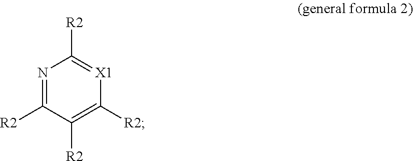

wherein, X1 is selected from C or N;

each R2 is independently selected from any one of group A, a substituted group A, group B and a substituted group B, and at least two of all R2s are group A or substituted group A, and at least one of R2s is group B or substituted group B;

the group A has a formula of any one of:

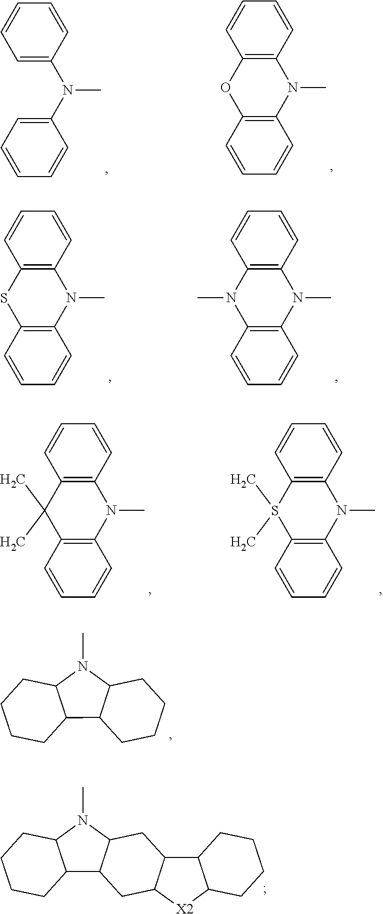

wherein, X2 is selected from any one of N, O and S;

the group B has a formula of any one of:

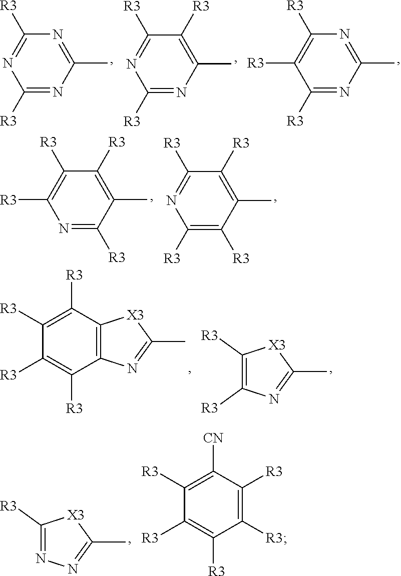

wherein, X3 is selected from O or S; each R3 is independently selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group.

Optionally, the second guest material has the following general formula 3:

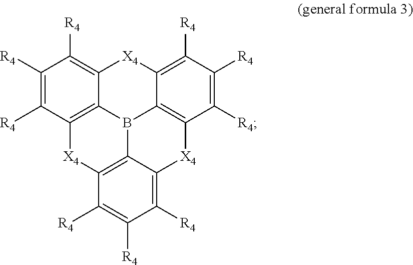

wherein each R4 is independently selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group;

each X4 is independently selected from any one of a single bond, O, S and N—R5; the single bond refers to that two benzene rings connected to X4 are directly connected through the single bond; R5 is selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group.

In a second aspect, embodiments of the present disclosure provide a display substrate, comprising a base and at least one light-emitting device provided on the base; wherein at least one light-emitting device of all light-emitting devices is the above-described light-emitting device.

Optionally, the display substrate is a display substrate.

### BRIEF DESCRIPTION OF DRAWINGS

FIG. 1 is a structural schematic diagram of a light-emitting device according to an embodiment of the present disclosure.

FIG. 2 is a schematic diagram of an energy interaction principle of the light-emitting device according to an embodiment of the present disclosure.

FIG. 3 is a structural schematic diagram of another light-emitting device according to an embodiment of the present disclosure.

FIG. 4 shows the emission spectrum of the first light-emitting layer and the absorption spectrum of the second light-emitting layer in the light-emitting device according to an embodiment of the present disclosure.

FIG. 5 shows the emission spectrum of the light-emitting device and the emission spectrum of the first guest material according to an embodiment of the present disclosure.

FIG. 6 shows emission spectra of Comparative Example 1, Comparative Example 2 and Example 1 of the present disclosure.

### DETAILED DESCRIPTION OF EMBODIMENTS

To enable those skilled in the art to better understand the technical embodiments of the present disclosure, examples of the present disclosure will be described in detail below with reference to the accompanying drawings and specific embodiments.

It would be understood that the specific embodiments and accompanying drawings described herein are merely illustrative of the examples of the present disclosure and are not to be considered as limiting the present disclosure.

It would be understood that in the absence of conflict, the various embodiments of the present disclosure and the various features in the embodiments may be combined with each other.

It would be understood that, for convenience of description, only parts related to the embodiments of the present disclosure are shown in the drawings of the embodiments of the present disclosure, and parts not related to the embodiments of the present disclosure are not shown in the drawings.

In the first aspect, embodiments of the present disclosure provide a light-emitting device, comprising a cathode, an anode, and both a first light-emitting layer and a second light-emitting layer provided between the cathode and the anode, wherein the first light-emitting layer is located on a side of

the second light-emitting layer close to the anode; wherein, the first light-emitting layer comprises a first host material and a first guest material, and the first host material has a hole mobility higher than an electron mobility;

the second light-emitting layer comprises a second host material and a second guest material, and the second host material has a hole mobility higher than an electron mobility;

S1(h1)>S1(g1), T1(h1)>T1(g1), S1(g1)−T1(g1)≤0.1 eV;

S1(h2)>S1(g2), T1(h2)>T1(g2), S1(g2)−T1(g2)≤0.1 eV;

S1(h1)≥S1(h2)>S1(g1)>S1(g2), T1(h1)≥T1(h2)>T1(g1)>T1(g2);

wherein T1 represents a triplet excitation energy, S1 represents a singlet excitation energy, h1 represents the first host material, h2 represents the second host material, g1 represents the first guest material, and g2 represents the second guest material;

the second guest material is a thermally activated delayed fluorescence material; and

at least 40% of an area in a region covered under the emission spectrum of the first light-emitting layer overlaps with the region covered under the absorption spectrum of the second light-emitting layer.

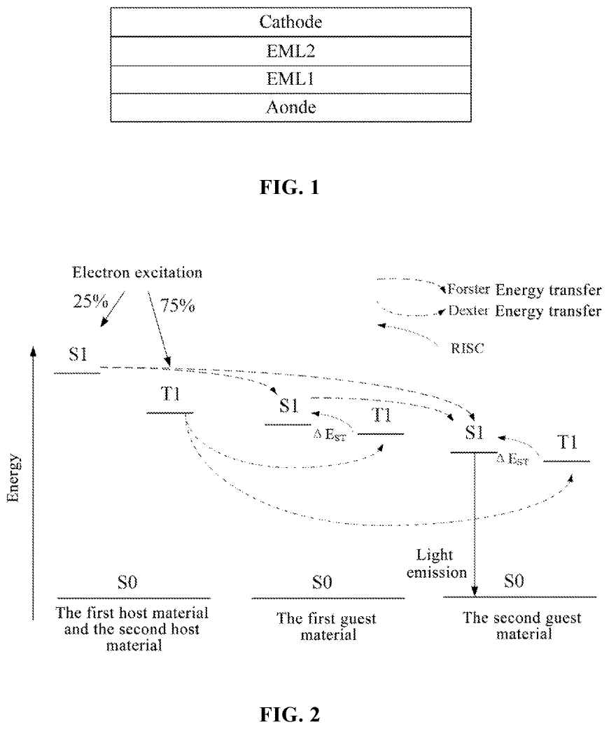

Referring to FIG. 1, the light-emitting device of the present embodiment comprises an anode (Anode), a cathode (Cathode), and a first light-emitting layer (EML 1) and a second light-emitting layer (EML 2) sandwiched between the cathode and the anode, wherein the first light-emitting layer is closer to the anode than the second light-emitting layer.

Specifically, both of the light-emitting layers comprise host materials (first host material, second host material) and guest materials (first guest material, second guest material), respectively, so that the light-emitting device is an organic light-emitting diode (OLED) light-emitting device.

In addition, the materials of the respective light-emitting layers further satisfy the following properties:

(1) In each light-emitting layer, the host material has a hole mobility higher than an electron mobility.

(2) In each light-emitting layer, the singlet excitation energy (S1) and the triplet excitation energy (T1) of the host material are higher than the corresponding energies of the guest material; meanwhile, the difference between S1 and T1 is less than 0.1 eV (electron volts) for the guest material, i.e., the energy band difference (band gap) ΔE_{ST} is small for the guest material.

(3) S1(h1) and T1(h1) of the first host material in the first light-emitting layer are equal to or higher than S1(h2) and T1(h2) of the second host material in the second light-emitting layer, respectively; and S1(g1) and T1(g1) of the first guest material in the first light-emitting layer are higher than S1(g2) and T1(g2) of the second guest material in the second light-emitting layer, respectively; moreover, S1(h2) and T1(h2) of the second host material in the second light-emitting layer are higher than S1(g1) and T1(g1) of the first guest material in the first light-emitting layer, respectively.

(4) At least the second guest material is a thermally activated delayed fluorescence (TADF) material, i.e. a material that emits a thermally activated delayed fluorescence.

(5) The first light-emitting layer has an emission spectrum wherein at least 40% of the emission spectrum is overlapped with the absorption spectrum of the second light-emitting layer. That is, with reference to FIG. 4, there is a certain region under the emission spectrum (with wavelength on the abscissa and light intensity on the ordinate) of the first light-emitting layer, there is also a certain region under the absorption spectrum of the second light-emitting layer, and the region under the emission spectrum of the first light-emitting layer overlaps with the region under the absorption spectrum of the second light-emitting layer by at least 40% in terms of area.

FIG. 2 shows the energy level distributions of the two host materials and the two guest materials in the two light-emitting layers.

In FIG. 2, S0 represents the ground state energy; 25% and 75% of the “electron excitation” indicate that after electron-hole recombination, there is 25% of the singlet energy and 75% of the triplet energy according to basic physical principles.

In FIG. 2, for example, the first host material and the second host material are the same material. That is, T1(h1) is equal to T1(h2), and S1(h1) is also equal to S1(h2) for the two host materials.

It can be seen that good Dexter energy transfer can occur both between T1(h1)/T1(h2) of the host material in the first light-emitting layer/the second light-emitting layer and T1(g1) of the guest material in the first light-emitting layer; and between T1(h1)/T1(h2) of the host material in the first light-emitting layer/the second light-emitting layer and T1(g2) of the guest material in the second light-emitting layer, thus allowing the energy transfer to the triplet state of the two guest materials, which is then transferred to the singlet state by reverse intersystem crossing (RISC) of the TADF material.

Meanwhile, since at least 40% of the area under the emission spectrum of the first light-emitting layer overlaps with the area under the absorption spectrum of the second light-emitting layer, good Forster energy transfer can occur between S1(h1)/S1(h2) of the host material in the first light-emitting layer/the second light-emitting layer and S1(g1) of the guest material in the first light-emitting layer; between S1(h1)/S1(h2) of the host material in the first light-emitting layer/the second light-emitting layer and S1(g2) of the guest material in the second light-emitting layer; and between S1(g1) of the guest material in the first light-emitting layer and S1(g2) of the guest material in the second light-emitting layer; this indicates that the first light-emitting layer can provide efficient Forster energy transfer to the second light-emitting layer.

Therefore, in the dual light-emitting layer structure of the present embodiment, the electron holes in the first light-emitting layer and the second light-emitting layer can be combined to form excitons, and the light are mainly (or totally) emitted by the second light-emitting layer, so that the separation of a light-emitting center and a recombination center is realized to a certain extent, thereby reducing the non-radiative effect and improving the stability of the device; meanwhile, the structure can realize energy transfer in various channels, thereby realizing the high-efficiency utilization of triplet excitons, reducing self-quenching and improving the emission efficiency; in addition, the two light-emitting layers only need to meet simple requirements for energy level and spectrum, so there is a wide range for selectable materials, and the problem of difficulty in material development does not exist.

Optionally, the second guest material has an emission spectrum with a full width at half maximum (FWHM) of 35 nm or less.

As described above, the light-emitting device according to the present embodiment emits light mainly by relaying on the second guest material, and therefore, the emission spectrum of the second guest material should be narrow so that the color emitted therefrom is “purer”, thereby further improving the color gamut.

Optionally, the energy of the light emitted by the first guest material accounts for less than 20% of total energy of the light emitted by the light-emitting device.

As described above, in the light-emitting device according to the present embodiment, since the light is mainly emitted from the second light-emitting layer (second guest material) after energy is transferred to the second light-emitting layer, the proportion of the light emitted by the first guest material should be as small as possible in the final overall light output of the light-emitting device.

Optionally, in the first light-emitting layer, the first host material has a mass percentage content of between 60% and 95%, and the first guest material has a mass percentage content of between 5% and 40%.

Optionally, in the second light-emitting layer, the second host material has a mass percentage content of between 70% and 99%, and the second guest material has a mass percentage content of between 1% and 30%.

In the first light-emitting layer, the mass percentage content of the first host material may be between 60% and 95%, preferably between 70% and 90%, and more preferably between 75% and 85%; and the mass percentage of the first guest material may be between 5% and 40%, preferably between 10% and 30%, and more preferably between 15% and 25%.

In the second light-emitting layer, the mass percentage content of the second host material is between 70% and 99%, preferably between 80% and 95%, and more preferably between 85% and 90%; and the mass percentage of the second guest material is between 1% and 30%, preferably between 5% and 20%, and more preferably between 10% and 15%.

As used herein, the expression “the mass percentage content of B in A” means that B is a part of A, and the relative percentage of B by mass based on 100% of the total mass of A (which includes B).

Optionally, at least one of the first host material, the first guest material, and the second host material is a thermally activated delayed fluorescence material.

As one implementation of the present embodiment, one or more of the first host material, the first guest material, and the second host material may be a TADF material, so as to further improve the light emission efficiency.

Optionally, the first host material and the second host material are the same material.

As one implementation of the present embodiment, the first host material and the second host material may be the absolutely same materials for simplicity.

Optionally, the first light-emitting layer has a thickness of between 5 nm and 15 nm.

Optionally, the second light-emitting layer has a thickness of between 1 nm and 20 nm.

The thickness of the first light-emitting layer may be between 5 nm and 15 nm, and further between 8 nm and 12 nm.

The thickness of the second light-emitting layer may be between 1 nm and 20 nm, and further between 5 nm and 15 nm.

Optionally, the light-emitting device further comprises at least one of the following structures:

an hole injection layer, a hole transport layer, a hole blocking layer, an electron injection layer, an electron transport layer, an electron blocking layer, a capping layer and a encapsulating layer.

In embodiments of the present disclosure, the light-emitting device may comprise other layer structures, which should be located at their respective positions, if present.

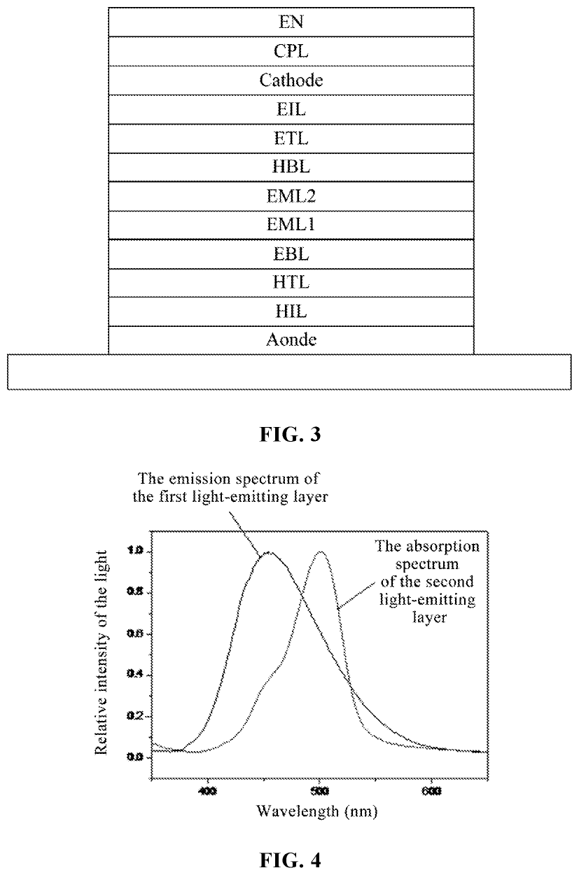

For example, with reference to FIG. 3, the anode of the light-emitting device is provided on the base, and starting from the anode, in a direction gradually away from the base, the light-emitting device may sequentially comprise: an anode (Aonde), a hole injection layer (HIL), a hole transport layer (HTL), an electron blocking layer (EBL), a first light-emitting layer (EML 1), a second light-emitting layer (EML 2), a hole blocking layer (HBL), an electron transport layer (ETL), an electron injection layer (EIL), a cathode (Cathode), a capping layer (CPL), and an encapsulating layer (EN).

Among these layers, Aonde is the “positive electrode” of the light-emitting device, and can be a material with high work function. When the light is emitted from the anode side (in the case that the light-emitting device adopts a bottom emission structure), the anode may be made of transparent oxides such as ITO (indium tin oxide), IZO (zinc tin oxide) and the like, and the anode may have a thickness of 80 nm to 200 nm. When the light is emitted from the cathode side (in the case that the light-emitting device adopts a top emission structure), the anode may be a composite structure of metal layer and transparent oxide layer, such as Ag/ITO or Ag/IZO and so on, wherein the metal layer may have a thickness of 80 nm to 100 nm, and the portion at the metal oxide side may have a thickness of 5 nm to 10 nm, such that a reference value of the reflectivity is 85% to 95% for the whole anode.

The hole injection layer (HIL), which is mainly used for lowering the hole injection barrier and improving the hole injection efficiency, may be a single-layer film of HAT-CN (2,3,6,7,10,11-hexacyano-1,4,5,8,9,12-hexaazatriphenylene), CuPc (copper phthalocyanine) and the like, or may be obtained by P-type doping the hole transport layer material, such as NPB (N,N′-diphenyl-N,N-(1-naphthyl)-1,1′-biphenyl-4,4′-diamine):F4TCNQ (2,3,5,6-tetrafluoro-7,7′,8,8′-tetracyanodimethyl-p-benzoquinone), TAPC (4,4′-cyclohexyl-bis[N,N-bis(4-methylphenyl) aniline]):MnO₃ (manganese trioxide) and the like, wherein the doping concentration (mass percentage content) may be 0.5% to 10%. The hole injection layer may have a thickness of 5 nm to 20 nm.

The hole transport layer (HTL), which is mainly used for transporting holes, may adopt the materials with high hole mobility, such as carbazole-based materials, wherein the materials have a highest occupied molecular orbital (HOMO) energy level of between −5.2 eV and −5.6 eV, and a thickness of 100 nm to 140 nm.

The electron blocking layer (EBL), which is mainly used for transporting holes and blocking electrons and excitons generated by the light-emitting layer, may has a thickness of 1 nm to 10 nm.

The first light-emitting layer (EML 1), which is the above-described first light-emitting layer, may be formed by co-evaporation of the first host material and the first guest material.

The second light-emitting layer (EML 2), which is the above-described second light-emitting layer, may be formed by co-evaporation of the second host material and the second guest material.

The hole blocking layer (HBL), which is mainly used for transporting electrons and blocking holes and excitons generated by the light-emitting layer, may has a thickness of 2 nm to 10 nm.

The electron transport layer (ETL), which is mainly used for transporting electrons, may be formed by blending thiophene derivatives, imidazole derivatives, azine derivatives and the like with lithium quinolinate, wherein the lithium quinolinate may have a mass percentage content of 30% to 70%. The electron transport layer may have a thickness of 20 nm to 70 nm.

The electron injection layer (EIL), which is mainly used for improving electron injection efficiency, may be made of LiF (lithium fluoride), LiQ (tert-butyl lithium), Yb (ytterbium), Ca (calcium), and the like; the electron injection layer may have a thickness of 0.5 nm to 2 nm.

The cathode (Cathode), which is a “negative electrode” of the light-emitting device, may be made of metal materials such as Mg (magnesium), Ag (silver), Al (aluminum) and the like, or made of alloy materials of Mg and Ag (wherein the mass ratio of Mg to Ag may be 3:7 to 1:9). When the light is emitted from the cathode side (in the case that the light-emitting device adopts a top emission structure), the cathode may have a thickness of 10 nm to 20 nm. When the light is emitted from the anode side (in the case that the light-emitting device adopts a bottom emission structure), the cathode may have a thickness of 80 nm or more, so as to ensure a good reflectivity.

The capping layer (CPL) has a higher refractive index to regulate light output and form a resonant microcavity, thus improving the color of the output light. The capping layer should have a refractive index of larger than 1.8 for the light at a wavelength of 460 nm, and may be formed by evaporation of organic small molecule materials. The capping layer may have a thickness of 50 nm to 80 nm.

The encapsulation layer (EN) is used for “sealing” the other structures of the light-emitting device, in order to protect them (especially the light-emitting layer) from external water, oxygen, and the like. The encapsulation layer may adopt an encapsulation adhesive, an encapsulation film, or a composite structure formed by stacking the organic layer(s) and the inorganic layer(s).

The following describes specific substances that can be used for the first host material, the second host material, the first guest material, and the second guest material in the light-emitting device according to embodiments of the present disclosure.

Optionally, the first host material and the second host material are each independently selected from materials having the following general formula 1:

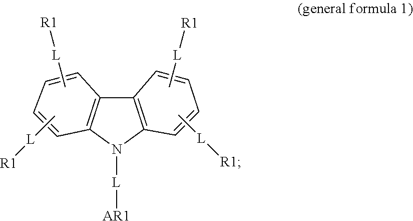

wherein each L is independently selected from any one of a single bond, a substituted C6-C30 arylene group and an unsubstituted C6-C30 arylene group; the single bond refers to that R1 corresponding to L is directly connected with benzene ring through the single bond, or AR1 corresponding to L is directly connected with N (nitrogen) through the single bond;

AR1 is selected from any one of a substituted C6-C30 aryl group, an unsubstituted C6-C30 aryl group, a substituted C2-C30 heterocyclic group, an unsubstituted C2-C30 heterocyclic group, a substituted C6-C30 arylamine group, an unsubstituted C6-C30 arylamine group, a substituted C8-C30 group containing aryl and heterocyclic groups, and an unsubstituted C8-C30 group containing aryl and heterocyclic groups;

each R1 is independently selected from any one of hydrogen, a substituted C1 -C20 alkyl, an unsubstituted C1 -C20 alkyl, a substituted C6-C30 aryl, an unsubstituted C6-C30 aryl, a substituted C2-C30 heterocyclic group, an unsubstituted C2-C30 heterocyclic group, a substituted C8-C30 group containing aryl and heterocyclic groups, an unsubstituted C8-C30 group containing aryl and heterocyclic groups, a substituted nitrile group, an unsubstituted nitrile group, a substituted isonitrile group, an unsubstituted isonitrile group, hydroxyl group, thiol group; R1 connected with different L are not connected with each other, or are connected with each other to form a ring structure;

at least one among AR1 and all R1 s is selected from any one of carbazolyl R(a), a substituted carbazolyl R(a), terphenylene R(b), and a substituted terphenylene R(b):

R(a) has a formula of:

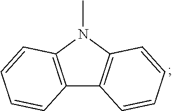

and

R(b) has a formula of:

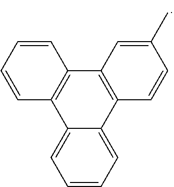 [SMILES: Cc1ccc2c3ccccc3c3ccccc3c2c1]

As one implementation of the present embodiment, both the first host material and the second host material may be selected from the materials of the above general formula 1, and the specific materials of the first host material and the second host material may be the same or different.

The connection manner of L-R1 chain on the benzene ring in the general formula 1 indicates that each L-R1 chain may be connected at any connectable position of the corresponding benzene ring, so that the two L-R1 chains on each benzene ring may be in any position relationship such as ortho-position, para-position, meta-position.

“R1 connected with different L are not connected with each other, or are connected with each other to form a ring structure” means that in each molecule of general formula 1, there may be no direct linkage between two different L-R1 chains, or alternatively, a linkage may be formed between R1 of the two L-R1 chains (provided that a linkage can be formed between the two R1), thereby forming a cyclic structure. In addition, the two L-R1 chains that are connected to form a ring are typically “adjacent”, for example, attached to the same benzene ring, and preferably located in ortho-position.

The number behind C represents the total number of carbon atoms in the corresponding group; and similarly hereinafter.

“A group is a single bond” may also be understood that the group is “absent”. That is, two other groups linked respectively to the group A are in fact directly connected through a single bond; and similarly hereinafter.

“the substituted group A” refers to a group formed by substituting at least one of hydrogen atoms in the group A with another element or group, for example, the hydrogen atom may be substituted with halogen, a short-chain (e.g., C1-C 5) alkyl, aryl and the like; and similarly hereinafter. Correspondingly, “an unsubstituted group” means that hydrogen atoms in the group would not be substituted with other groups; and similarly hereinafter.

When the group is a hydrogen element, it also comprises an isotope of hydrogen, particularly an isotope deuterium (D); and similarly hereinafter. Deuterium is beneficial to improve the stability of the molecule, because it is relatively heavy.

“The group A containing an aryl and heterocyclic group” means that the group A comprises both aromatic ring and heterocyclic group; or alternatively, the group A is “a mix” of aryl and heterocyclic group; and similarly hereinafter.

Optionally, the first guest material has the following general formula 2:

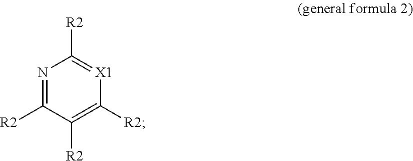

wherein, X1 is selected from C (carbon) or N (nitrogen);

each R2 is independently selected from any one of group A, a substituted group A, group B and a substituted group B, and at least two of all R2s are group A or substituted group A, and at least one R2 is group B or substituted group B;

the group A has a structural formula of any one of:

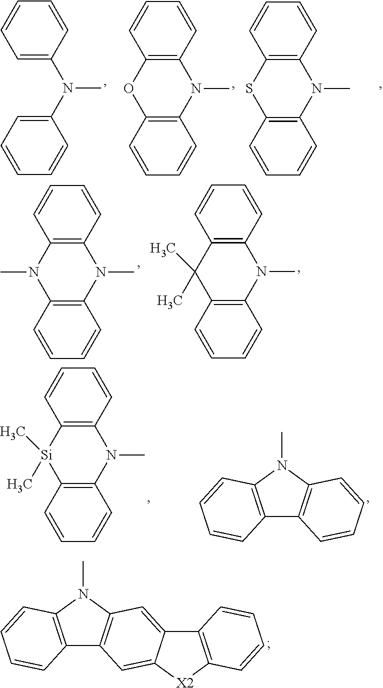

wherein, X2 is selected from any one of N (nitrogen), O (oxygen) and S (sulfur);

the group B has a structural formula of any one of:

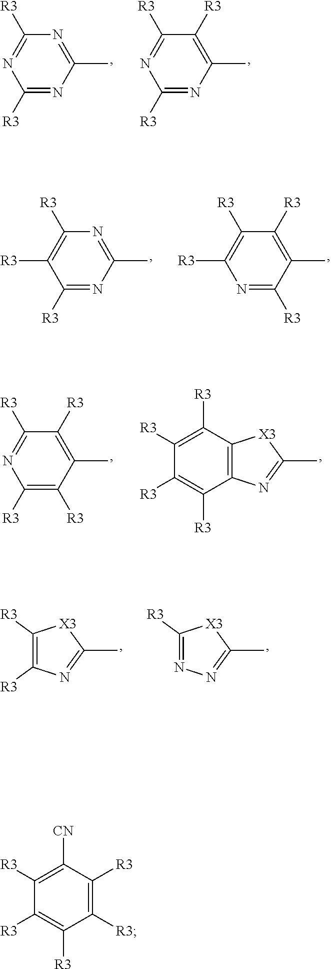

wherein, X3 is selected from O (oxygen) or S (sulfur); each R3 is independently selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group.

When the above-described R3 is a substituted alkyl group or a substituted alkoxyl group, its hydrogen is preferably substituted with halogen, i.e. R3 may be a haloalkyl group or a haloalkoxyl group; further, if there are also hydrogens in the haloalkyl group or the haloalkoxyl group, these hydrogens may also be substituted with the groups other than halogens, i.e. R3 may be a substituted haloalkyl group or a substituted haloalkoxyl group.

Optionally, the second guest material has the following general formula 3:

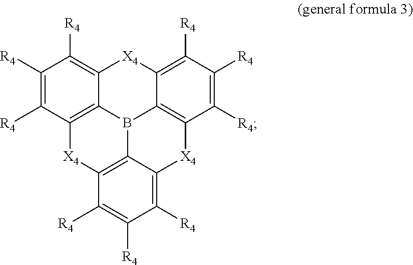

wherein each R4 is independently selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group;

each X4 is independently selected from any one of a single bond, O (oxygen), S (sulfur) and N(nitrogen)-R5; the single bond means that two benzene rings connected with X4 are directly connected through the single bond; R5 is selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group.

When the above-described R4 is a substituted alkyl group or a substituted alkoxyl group, its hydrogen is preferably substituted with halogen, i.e. R4 may be a haloalkyl group or a haloalkoxyl group; further, if there are also hydrogens in the haloalkyl group or the haloalkoxyl group, these hydrogens may also be substituted with the groups other than halogens, i.e. R4 may be a substituted haloalkyl group or a substituted haloalkoxyl group.

Further, the light-emitting devices of the prior art (Comparative Example 1 and Comparative Example 2) and the light-emitting device of the present embodiment (Example 1) were respectively prepared using commercially available materials, and their structures were specifically as follows:

### Comparative Example 1 (Bottom Emission Structure)

Aonde (ITO) (70 nm)/HIL (commercially available material) (10 nm)/HTL (commercially available material) (160 nm)/EBL (commercially available material) (10 nm)/EML (75% commercially available host material: 25% commercially available TADF material) (25 nm)/HBL (commercially available material) (5 nm)/ETL (commercially available material) (40 nm)/EIL (commercially available material) (1 nm)/Cathode (80% Mg:20% Ag) (160 nm).

### Comparative Example 2 (Bottom Emission Structure)

Anode (ITO) (70 nm)/HIL (commercial available material) (10 nm)/HTL (commercial available material) (160 nm)/EBL (commercial available material) (10 nm)/EML (75% commercial available host material: 24% commercial available TADF material: 1% commercial available conventional fluorescent material other than TADF) (25 nm)/HBL (commercial available material) (5 nm)/ETL (commercial available material) (40 nm)/EIL (commercial available material) (1 nm)/Cathode (80% Mg:20% Ag) (160 nm).

### Example 1 (with Reference to Bottom Emission Structure of FIG. 3)

Anode (ITO) (70 nm)/HIL (commercial available material) (10 nm)/HTL (commercial available material) (160 nm)/EBL (commercial available material) (10 nm)/EML1 (80% commercial available first host material:20% commercial available first guest material) (10 nm)/EML 2 (75% commercial available second host material:25% commercial available second guest material) (15 nm)/HBL (commercial available material) (5 nm)/ETL (commercial available material) (40 nm)/EIL (commercial available material) (1 nm)/Cathode (80% Mg:20% Ag) (160 nm).

EML represents a single light-emitting layer in the Comparative Examples.

The first parenthesis behind each structure indicates the material adopted by the structure, if the material is a mixture of a plurality of materials, the percentage represents the mass percentage content of the corresponding material; and the second parenthesis behind the structure indicates the thickness of the structure.

The first host material and the second host material in Example 1 are the same, and are the same as the host materials of the light-emitting layers in Comparative Examples 1 and 2.

The energy levels of the first host material/the second host material (both of which are the same), the first guest material, and the second guest material used in Example 1 are as follows:

TABLE 1
Parameters of materials used in Example 1

| Materials | S1 (eV) | T1 (eV) | ΔEst (eV) |
|---|---|---|---|
| The first host material and the | 2.85 | 2.72 | 0.13 |
| second host material | | | |
| The first guest material | 2.7 | 2.6 | 0.1 |
| The second guest material | 2.28 | 2.23 | 0.05 |

It can be seen that the energy levels of the above materials meet the requirements of the embodiments of the present disclosure.

With reference to FIG. 4, it can be seen that the emission spectrum of the first light-emitting layer and the absorption spectrum of the second light-emitting layer in Example 1 meet the requirement that “at least 40% of the region covered under the emission spectrum of the first light-emitting layer overlaps with the region covered under the absorption spectrum of the second light-emitting layer in terms of area”.

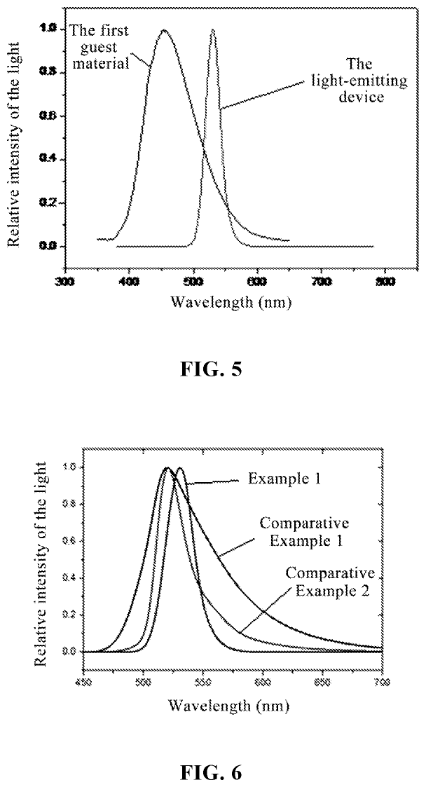

The emission spectrum of the first guest material and the emission spectrum of the light-emitting device in Example 1 are shown in FIG. 5. It can be seen that the emission spectrum of the light-emitting device is entirely flat at the position corresponding to the main peak of the emission spectrum of the first guest material (i.e., the light-emitting device emits no light at this wavelength). This indicates that the light emitted from the light-emitting device has no component derived from the first guest material at all, that is, the energy of the light emitted by the first guest material accounts for 0% of the light emitted from the light-emitting device (inherently in accordance with the requirement of “less than 20%”).

It can be seen that the properties of the materials used in the light-emitting device in Example 1 meet the requirements of the embodiments of the present disclosure.

The light-emitting devices of Comparative Example 1, Comparative Example 2, and Example 1 were tested for voltage, light-emitting efficiency, color coordinates (color coordinates in CIE1931 color space), full width at half maximum (FWHM), lifetime (LT 95, the time taken for the emission luminance to decrease to 95% of the initial value) at a current density of 15 mA/cm², respectively, and the results are as follows:

TABLE 2
Performance comparison between Example and Comparative Examples

| | | Light-emitting | Color | | |
|---|---|---|---|---|---|
| No. | Voltage | efficiency | coordinates | FWHM | FWHM |
| Comparative | 100% | 100% | (0.31, 0.61) | 63 nm | 100% |
| Example 1 | | | | | |
| Comparative | 98% | 97% | (0.24, 0.70) | 30 nm | 110% |
| Example 2 | | | | | |
| Example 1 | 99% | 113% | (0.19, 0.76) | 26 nm | 88% |

In TABLE 1, all the percentage data represent the relative percentage of the test results of other Comparative Examples and Examples, when the test value of Comparative Example 1 is 100%.

The emission spectra of the light-emitting devices of Comparative Example 1, Comparative Example 2, and Example 1 were measured, respectively, and the results are shown in FIG. 6.

As can be seen from the above results, the light-emitting device of Example 1 had a significantly higher light-emitting efficiency than each Comparative Example, and a significantly lower full width at half maximum than each Comparative Example.

The light-emitting device provided by the embodiment of the present disclosure has advantages of higher light-emitting efficiency, fully utilized energy, narrow light-emitting spectrum, and better color gamut.

In the second aspect, embodiments of the present disclosure provide a display substrate, comprising a base and at least one light-emitting device provided on the base; wherein at least one light-emitting device of all light-emitting devices is the above-described light-emitting device.

A display substrate capable of displaying an image can be obtained by providing a plurality of light-emitting devices on a base and controlling the light-emitting devices to emit light at a desired luminance, respectively.

Obviously, since the above light-emitting devices are organic light-emitting diode (OLED) light-emitting devices, the display substrates according to the present embodiments are organic light-emitting diode (OLED) display substrates.

The display substrate may further comprise a structure for controlling light emission of the light-emitting device such as a gate line, a data line, a pixel circuit (such as a 2T1C pixel circuit, and a 7T1C pixel circuit) and the like.

The light-emitting devices in the display substrate may be classified into different colors, thereby achieving color display.

In a third aspect, embodiments of the present disclosure provide a display equipment, comprising the display substrate described above.

The display substrate is assembled with other devices (such as an alignment substrate, a driving device, a power supply, and a housing) to obtain a display equipment which can be independently used.

Specifically, the display equipment may be any product or parts having a display function, such as an organic light-emitting diode (OLED) display panel, an electronic paper, a mobile phone, a tablet computer, a television, a display, a notebook computer, a digital photo frame, and a navigator.

It would be understood that the above embodiments are merely exemplary embodiments adopted to illustrate the principles of the embodiments of the present disclosure, but the present disclosure is not limited thereto. It will be apparent to those skilled in the art that various modifications and improvements may be made without departing from the spirit and scope of the present embodiments, and such modifications and improvements are also considered to be within the protection scope of the present disclosure.

1. A light-emitting device, comprising a cathode, an anode, a first light-emitting layer and a second light-emitting layer, wherein the first light-emitting layer and the second light-emitting layer are provided between the cathode and the anode, the first light-emitting layer is located on a side of the second light-emitting layer close to the anode, wherein,
the first light-emitting layer comprises a first host material and a first guest material, and the first host material has a hole mobility higher than an electron mobility,
the second light-emitting layer comprises a second host material and a second guest material, and the second host material has a hole mobility higher than an electron mobility,
S1(h1)>S1(g1), T1(h1)>T1(g1), S1(g1)−T1(g1)≤0.1 eV;
S1(h2)>S1(g2), T1(h2)>T1(g2), S1(g2)−T1(g2)≤0.1 eV;
S1(h1)≥S1(h2)>S1(g1)>S1(g2), T1(h1)≥T1(h2)>T1(g1)>T1(g2);
wherein T1 represents a triplet excitation energy, S1 represents a singlet excitation energy, h1 represents the first host material, h2 represents the second host material, g1 represents the first guest material, and g2 represents the second guest material,
the second guest material is a thermally activated delayed fluorescence material; and
at least 40% of an area in a region covered under a emission spectrum of the first light-emitting layer overlaps with the area in the region covered under an absorption spectrum of the second light-emitting layer.

2. The light-emitting device according to claim 1, wherein the second guest material has an emission spectrum with a full width at half maximum of 35 nm or less.

3. The light-emitting device according to claim 1, wherein an energy of a light emitted by the first guest material accounts for less than 20% of a total energy of the light emitted by the light-emitting device.

4. The light-emitting device according to claim 1, wherein in the first light-emitting layer, the first host material has a mass percentage content of between 60% and 95%, and the first guest material has a mass percentage content of between 5% and 40%.

5. The light-emitting device according to claim 1, wherein in the second light-emitting layer, the second host material has a mass percentage content of between 70% and 99%, and the second guest material has a mass percentage content of between 1% and 30%.

6. The light-emitting device according to claim 1, wherein at least one of the first host material, the first guest material and the second host material is a thermally activated delayed fluorescence material.

7. The light-emitting device according to claim 1, wherein the first host material and the second host material are the same material.

8. The light-emitting device according to claim 1, wherein the first light-emitting layer has a thickness of between 5 nm and 15 nm.

9. The light-emitting device according to claim 1, wherein the second light-emitting layer has a thickness of between 1 nm and 20 nm.

10. The light-emitting device according to claim 1, further comprising at least one of the following structures:
an hole injection layer, a hole transport layer, a hole blocking layer, an electron injection layer, an electron transport layer, an electron blocking layer, a capping layer and a encapsulating layer.

11. The light-emitting device according to claim 1, wherein the first host material and the second host material are each independently selected from materials having the following general formula 1: 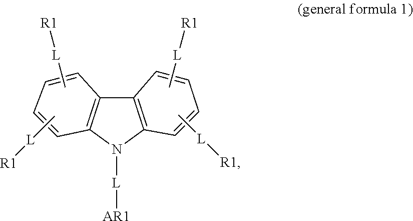
wherein each L is independently selected from any one of a single bond, a substituted C6-C30 arylene group and an unsubstituted C6-C30 arylene group; the single bond indicates that R1 corresponding to L is directly connected with benzene ring through the single bond, or AR1 corresponding to L is directly connected with N through the single bond;
AR1 is selected from any one of a substituted C6-C30 aryl group, an unsubstituted C6-C30 aryl group, a substituted C2-C30 heterocyclic group, an unsubstituted C2-C30 heterocyclic group, a substituted C6-C30 arylamine group, an unsubstituted C6-C30 arylamine group, a substituted C8-C30 group containing aryl and heterocyclic groups, and an unsubstituted C8-C30 group containing aryl and heterocyclic groups;
each R1 is independently selected from any one of hydrogen, a substituted C1-C20 alkyl, an unsubstituted C1-C20 alkyl, a substituted C6-C30 aryl, an unsubstituted C6-C30 aryl, a substituted C2-C30 heterocyclic group, an unsubstituted C2-C30 heterocyclic group, a substituted C8-C30 group containing aryl and heterocyclic groups, an unsubstituted C8-C30 group containing aryl and heterocyclic groups, a substituted nitrile group, an unsubstituted nitrile group, a substituted isonitrile group, an unsubstituted isonitrile group, hydroxyl group, thiol group; R1 connected with different Ls are not connected with each other, or are connected with each other to form a ring structure;
at least one among AR1 and all R1s is selected from any one of carbazolyl R(a), a substituted carbazolyl R(a), terphenylene R(b), and a substituted terphenylene R(b):
R(a) has a structural formula of: 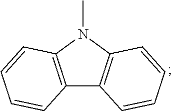
and
R(b) has a structural formula of:

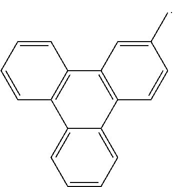 [SMILES: Cc1ccc2c3ccccc3c3ccccc3c2c1]

12. The light-emitting device according to claim 1, wherein the first guest material has the following general formula 2: 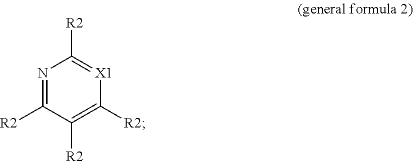
wherein, X1 is selected from C or N;
each R2 is independently selected from any one of group A, a substituted group A, group B and a substituted group B, and among all of R2s, at least two R2s are group A or substituted group A, and at least one R2 is group B or substituted group B;
the group A has a structural formula of any one of: 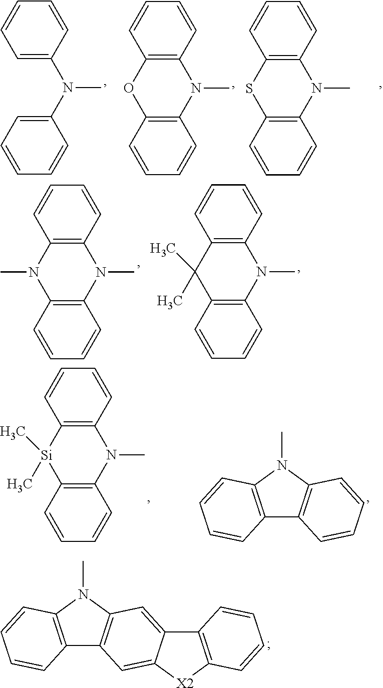
wherein, X2 is selected from any one of N, O and S;
the group B has a structural formula of any one of: 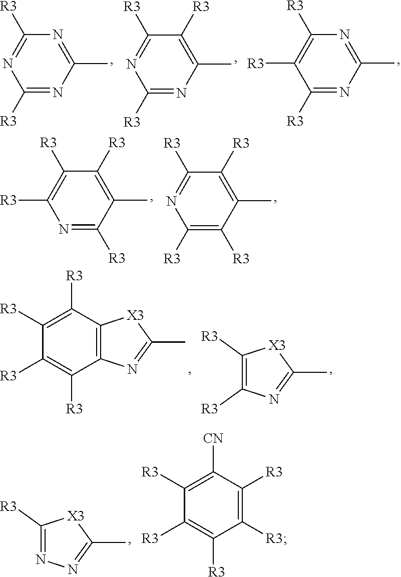
wherein, X3 is selected from O or S; each R3 is independently selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group.

13. The light-emitting device according to claim 1, wherein the second guest material has the following general formula 3: 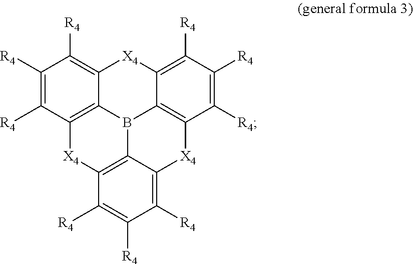
wherein each R4 is independently selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group;
each X4 is independently selected from any one of a single bond, O, S and N-R5; the single bond indicates that two benzene rings connected with X4 are directly connected through the single bond; R5 is selected from any one of hydrogen, a halogen group, a substituted silyl group, an unsubstituted silyl group, nitrile group, a substituted C1-C20 alkyl group, an unsubstituted C1-C20 alkyl group, a substituted C1-C20 alkoxyl group, an unsubstituted C1-C20 alkoxyl group, a substituted C6-C30 aryl group, an unsubstituted C6-C30 aryl group, a substituted C2-C30 heterocyclic group, and an unsubstituted C2-C30 heterocyclic group.

14. A display substrate comprising a base and at least one light-emitting device provided on the base; wherein at least one of all of the light-emitting devices is the light-emitting device according to claim 1.

15. A display substrate comprising a base and at least one light-emitting device provided on the base; wherein at least one of all of the light-emitting devices is the light-emitting device according to claim 2.

16. A display substrate comprising a base and at least one light-emitting device provided on the base; wherein at least one of all of the light-emitting devices is the light-emitting device according to claim 3.

17. A display substrate comprising a base and at least one light-emitting device provided on the base; wherein at least one of all of the light-emitting devices is the light-emitting device according to claim 4.

18. A display substrate comprising a base and at least one light-emitting device provided on the base; wherein at least one of all of the light-emitting devices is the light-emitting device according to claim 5.

19. A display equipment, comprising the display substrate according to claim 14.

20. The display equipment according to the claim 19, wherein the display equipment is selected from at least one of an organic light-emitting diode (OLED) display panel, an electronic paper, a mobile phone, a tablet computer, a television, a display, a notebook computer, a digital photo frame, and a navigator.
